(19) United States
(12) Patent Application Publication
(10) Pub. No.: US 2013/0093440 A1
(43) Pub. Date: Apr. 18, 2013

(54) CONTROL APPARATUS AND METHOD FOR DETECTING A TYPE OF LOAD

(71) Applicant: Gregor Maria Ernst Walter Aumann, Duesseldorf (DE)

(72) Inventor: Gregor Maria Ernst Walter Aumann, Duesseldorf (DE)

(73) Assignee: permundo GmbH, Duesseldorf (DE)

(21) Appl. No.: 13/642,196

(22) PCT Filed: Apr. 6, 2011
(86) PCT No.: PCT/EP2011/001696

§ 371 Date: Dec. 19, 2012

(30) Foreign Application Priority Data
Apr. 19, 2010 (DE) 10 2010 015 625.6
Oct. 20, 2010 (DE) 10 2010 048 980.8

(51) Int. Cl. G01R 27/02

(52) U.S. Cl. CPC G01R 27/02
USPC 324/691

(57) ABSTRACT

The invention relates to a control apparatus (1) for controlling a load (4), wherein the control apparatus (1) can be connected between a voltage source (2) and the load (4), having a control circuit (8), a first switch (S3) which is driven by the control circuit (8) and controls a current flowing from the voltage source (2) to the load (4) in order to operate the load (4), and a load type detector (6). The invention proposes that the load type detector (6) comprises means (Z1, Z2, S1, S2) for applying a test signal to the load (4) and at least one measuring device (M1, M2), wherein, for the purpose of detecting the type of load (4), the control apparatus (1) is set up to carry out the following first detection steps:
driving of the means (Z1, Z2, S1, S2) for applying the test signal to the load (4) by means of the control circuit (8) with the first switch (S3) open, wherein the application of the test signal results in a test current flowing through is the load (4) and in a test voltage dropped across the load (4),
recording of at least one variable derived from the test current and/or the test voltage by means of the measuring device (M1, M2),
and detection of the type of load by analyzing the recorded variable.

The invention relates to a control apparatus for controlling a load, wherein the control apparatus can be connected between a voltage source and the load, having a control circuit and a load type detector. Furthermore, the invention relates to a method for detecting the load type of a load.

The majority of buildings are equipped with electronic devices to control electrical consumers. A frequently encountered configuration of such an electronic device is a light dimmer which is utilized to control brightness of lamps. A known problem with the use of light dimmers is the necessity that the control principle of the light dimmer must be adapted to the electrical properties of the lamp to be controlled and therefore the choice and installation of a dimmer suitable for the lamp to be controlled requires special know-how.

A known solution to this problem are so-called universal dimmers which determine the existence of an inductive portion in the complex load resistance of the lamp based on different measuring principles and which in case of the existence of such an inductive portion choose the forward phase control as controlling principle and which in case of the non-existence of such an inductive portion apply the reverse phase control as control principle.

Known from DE 43 10 723 A1, EP 0 618 667 B1 and EP 0 923 274 B1 are methods and devices in which a current pulse is initially charged to the load after applying the mains voltage and in which the existence of an inductive portion is recognized by the level of the voltage pulse occurring when turning-off the current pulse.

Known from WO 92/15052, U.S. Pat. No. 6,813,720 B2, EP 1 414 144 A1 and WO 2009/36515 A1 are further methods and devices in which the dimmer initially takes effect on the load in the sense of a reverse phase control and in which the control principle alternates on the occurrence of voltage pulses at the connections of the load and from then on takes effect on the load in the sense of a forward phase control.

For recognition of an inductive portion in the load, DE 197 51 828 B4 proposes to initially turn-on the load in the sense of a forward phase control shortly before the zero voltage crossing of the mains voltage and to turn-off the load again in the zero crossing of the load current and to repeat this procedure every next but one half-wave of the mains voltage, verifying whether the zero crossing of the load current has temporally shifted versus the zero voltage crossing of the mains voltage in order to conclude from a possible shifting on the existence of an inductive portion in the load.

In accordance with a method according to EP 1 313 205 B1, too, a test program is run initially after applying the mains voltage in which the load is turned-on in the zero voltage crossing of the mains voltage and in which it is verified during the subsequent turning-off of the load in the zero current passage of the load current whether it is temporally shifted relative to the zero voltage passage of the mains voltage, determining the type of load based on a possible shifting.

The recognition of a possible inductive load portion as known from prior art is merely sufficient to design and construct a control device that is exclusively suitable for lamps which use either high-voltage or low-voltage bulbs as illuminants. A control device of such a design, however, is unable to suitably control neither energy-saving lamps with an electronic ballast nor LED lamps. But this would be desirable, for example, for a universal dimmer because the latter illuminants have gained much popularity more recently.

In this regard, WO 2008/144095 A1 proposes a dimmer which can at least differentiate between a high-voltage bulb and an energy-saving lamp with electronic ballast. Desirable, however, would be a universal dimmer with which all lamps of a customary design can be controlled.

It is the object of the invention to provide a method and a device for controlling a load in an alternating current circuit that are suitable for a multitude of types of lamps which are used in private housing. For example, this includes high-voltage incandescent lamps, low-voltage incandescent lamps with magnetic or electronic ballast or so-called energy-saving lamps with fluorescent tubes or LEDs.

The problem underlying the invention is solved by a control apparatus with the characteristic features of patent claim 1 and by a method according to patent claim 22. Preferred embodiments of the invention are indicated in the dependent patent claims.

The invention relates to a control apparatus (1) for controlling a load (4), wherein the control apparatus (1) can be connected between a voltage source (2) and the load (4), having a control circuit (8), a first switch (S3) which is driven by the control circuit (8) and controls a current flowing from the voltage source (2) to the load (4) in order to operate the load (4), and a load type detector (6). The invention proposes that the load type detector (6) comprises means (Z1, Z2, S1, S2) for applying a test signal to the load (4) and at least one measuring device (M1, M2), wherein, for the purpose of detecting the type of load (4), the control apparatus (1) is set up to carry out the following first detection steps:

The invention relates to a control apparatus for controlling a load, wherein the control apparatus can be connected between a voltage source and the load, having a control circuit, a first switch which is driven by the control circuit and controls a current flowing from the voltage source to the load in order to operate the load, and a load type detector. The invention proposes that the load type detector comprises means for applying a test signal to the load and at least one measuring device, wherein, for the purpose of detecting the type of load, the control apparatus is set up to carry out the following first detection steps:
driving the means for applying the test signal to the load by means of the control circuit with the first switch open, wherein the application of the test signal results in a test current flowing through the load and in a test voltage being dropped across the load,
recording of at least one variable derived from the test current and/or the test voltage by means of the measuring device,
and detection of the type of load by analyzing the recorded variable.

Embodiments of the invention have the advantage in that different types of loads can be detected and driven in an appropriate manner. The invention enables the determination of a variable which is derived from the impedance of the load in the most general form, i.e. with an ohmic, inductive, and capacitive portion. By way of a suitable analysis of these variables, it is furthermore possible to make statements on a possible non-linear behavior of the load, i.e. temporal changes of the impedance when applying the test signal. The actual detection procedure can advantageously remain invisible towards the outside, because at first it can be executed within a very short time and secondly because the test current occurring here can be limited in a manner that the load is not driven as intended (i.e. outside the specifications given by manufacturers). Avoidance of an operation as intended means in terms of the invention that the load shows no reaction recognizable for a user. In case the load is a lamp, it means that no luminescence is recognizable for a user. Operation as intended is avoided by way of a suitable limitation of the current intensity of the test current as well as by applying a test signal to the load, if required, over a (limited) predetermined period of time. The prior condition is that means for applying a test signal to the load are inventively provided for which are capable of generating the test signal, while the first switch which forms the “main switch” for controlling regular operation is open. The control circuit of the inventive device thus provides for that the first detection steps can be carried out with the load being turned off. With regard to amplitude and duration, the test signal can be generated independently of the supply voltage of the load.

Upon detection of the type of load, the test signal can inventively be interrupted (at least for the time being) or the test current can be reduced. This measure in turn serves for avoiding a permanent test current flow through the load that might lead to an undesirable reaction of the load recognizable from the outside. To ensure that the execution of the first detection steps remains (by and large) unperceivable for the user, the duration of executing the first detection steps in total should amount to maximally 200 ms, preferably maximally to 100 ms.

In accordance with a development of the inventive device, it is furthermore set up to carry out the following second detection steps subsequent to the first detection steps:
abolition of the interruption and/or of the reduction of the test current during a defined time interval, with the first switch being continually open,
detection of the at least one variable derived from the test current and/or test voltage by means of the measuring device during the abolition of the interruption and/or reduction of the test current,
detection of a separation and/or restoration of the connection between the control apparatus and the load by analyzing the recorded variable. Alternatively, the following second detection steps can be carried out:
driving the means for applying the test signal to the load by the control circuit with the first switch open,
recording the at least one variable derived from the test current and/or test voltage by the measuring device,
detection of a separation and/or establishment of the connection between the control apparatus and the load by analyzing the recorded variable. With these configurations, the test signal is applied to the load, wherein the test signal is generated during the second detection steps preferably in such a manner that the test current has a current intensity reduced as compared with the first detection steps or flows only intermittently (e.g. every 100 ms). In this way it is intended to be ensured that there is no reaction of the load (e.g. brief luminescence with a lamp) visible for a user from the outside or that no damage is caused to the load, even though the second detection steps are repeated over several minutes or even hours. By analyzing the measuring variable recorded during the second detection steps, a separation of the load from the inventive control apparatus can be detected (with the load turned-off). For example, such a separation occurs if a user actuates an on-off switch directly allocated to the load or installed therein. The detection of a corresponding event can be utilized to automatically trigger appropriate actions. For example, the detection of the establishment of a connection can be utilized for closing the first switch of the inventive device in order to put the load in operation. In this manner, the user can utilize the on-off switch of the load as usual for turning the load on or off. Furthermore, the detection of this event can be transmitted to further devices in order to trigger appropriate actions there in remote control. For example, the detection of a manual on-off turning of the load can be utilized to automatically turn-off (also) another load (or several other loads). In other words, the second detection steps serve for ascertaining whether a load “is existing” at all.

Upon detection of a separation of a connection to the load, it may be sensible to begin again with the detection of the load by means of the first detection steps in order to take account of the case that the load originally connected with the inventive control apparatus is exchanged for another load.

It should be noted that it is irrelevant for the invention whether the first or the second detection steps are carried out at first. In particular, it is conceivable to initially carry out the second detection steps repeatedly until the establishment of a connection between the control apparatus and the load (e.g. by manual operation of the on-off switch) is detected. Afterwards, the type of load can be detected by means of the first detection steps before the load is activated by a corresponding driving of the first switch of the control apparatus. Furthermore, after activating the load, the flowing operating current can be monitored by means of the inventive control apparatus, e.g. in order to also detect a manual turning-off of the load.

In accordance with one embodiment of the invention, the control apparatus is set up to record a first variable derived from the test current and a second variable derived from the test voltage by the measuring device. This allows for making a comprehensive analysis of the load for the purpose of detecting the type of load. By evaluating the chronology of measuring variables, the type of load can be reliably detected, with it being possible for the load to comprise passive and active components, too.

In accordance with another embodiment of the invention, the control apparatus is furthermore set up to control after detection of the load type a current flowing from the voltage source to operate the load by means of the control circuit by appropriately driving the first switch according to a control method allocated to the type of load. This enables an optimal operation of the specific load and an appropriate control to obtain a desired operation status. An excessive burdening of the load can thus be avoided, for example, and the service life of the load can be increased. Besides, the invention makes it possible to operate the most different types of load with the same universal control apparatus, it means corresponding to the suitable individual “characteristic” of the load, e.g. for the purpose of dimming a lamp. Viable control methods in terms of the invention for example are the forward phase control or reverse phase control method.

According to another embodiment of the invention, the control apparatus comprises a communication unit connected with the control circuit, wherein the communication unit is configured to receive remote control data for remote control of the control apparatus and/or to send status and/or diagnostic data of the control apparatus. Thereby, a switching cycle to operate the load can be controlled in a flexible “remotely controlled” manner—either via an intelligent network or just simply by utilizing conventional means for switching (on) or remote controls. Likewise, a status change in the control apparatus, e.g. a removal of a load, can be communicated to other devices.

In accordance with another embodiment of the invention, the control apparatus comprises a zero voltage detector for detection of zero voltage crossings of the voltage source connected with the control apparatus, wherein the point of time of the beginning of the inventively carried out measurements relative to the point of time of a detected zero voltage crossing is predetermined. Owing to the existence of a “reference point”, this simplifies the determination of the type of load and thus it increases its reliability.

In accordance with another embodiment of the invention, the control apparatus, for the purpose of analyzing the chronology of the first and second variable, is set up to carry out several measurements of the first and/or second variable in the course of the predetermined period of time at different predetermined points of time.

For example, the control apparatus is set up to detect the type of load by comparing the measuring values obtained at different predetermined points of time with stored data characterizing the type of load. It means that the chronology of measuring values characteristic for a certain type of load is recognized by comparing it with a suitable number of reference curves defined by pre-stored reference values. Alternative approaches, which for example may be based on “neurofuzzy” approaches, are indeed conceivable.

In accordance with another embodiment of the invention, the control apparatus comprises a second switch which is driven by the control circuit and which separably connects the load via at least one impedance with the voltage source for applying the test signal to the load. The impedance determines the test current and is appropriately chosen for this purpose. The second switch is so driven by the control circuit that the test current flows only during a predetermined period of time. Alternatively, an impedance switched in parallel to the first switch and a second switch driven by the control circuit may be provided for which separably switches a further impedance in parallel to the load for limiting the test current flowing through the load. In terms of switching circuitry, both variants can be realized with little expenditure.

In accordance with another embodiment of the invention, the first switch and the second switch are alternately opened or closed. With this configuration, the detection of the type of load is carried out exclusively during the time when the load is out of operation.

In accordance with another embodiment of the invention, the control apparatus is set up for periodically repeated execution of the first and/or second detection steps. Thereby it can be permanently monitored whether the type of load changes and/or whether a load is at all present or not. The periodic repetition can furthermore be utilized by statistical averaging to increase the accuracy and reliability in load type detection.

In accordance with another embodiment of the invention, the control apparatus is furthermore set up to carry out the following third detection steps:
applying an operating current to the load by closing the first switch,
recording at least one variable derived from the operating current and/or from the operating voltage dropped across the load by the at least one measuring device,
detection of the type of load by analyzing the variable recorded. Accordingly, the detection of the load type (first and second detection steps) which according to the invention lies outside the regular operation of the load is complemented by load type detection during regular operation, i.e. with the first switch closed (third detection steps). Thereby, it is also possible to detect loads whose load type cannot be identified or not clearly be identified just by applying the test current. The detection of the load type, in turn, is expediently accomplished by analyzing the chronology of the variables derived from the operating current and operating voltage by carrying out several measurements of the recorded variable(s) at different predetermined points of time, wherein the load type is then detected by comparing the measuring values obtained at different predetermined points of time with stored data characterizing the type of load. Expediently, the variables recorded during the first and third detection steps are combined in the load type detection in order to be able to exactly identify the load in all relevant cases. The detection of the load type during regular operation may advantageously also be comprised of a measurement of the power input of the load in order to compare it with the nominal power input.

In another aspect, the invention relates to a computer program product with instructions executable by a processor to carry out the afore-mentioned detection steps.

Practical examples of the invention are elucidated in the following based on drawings, wherein:

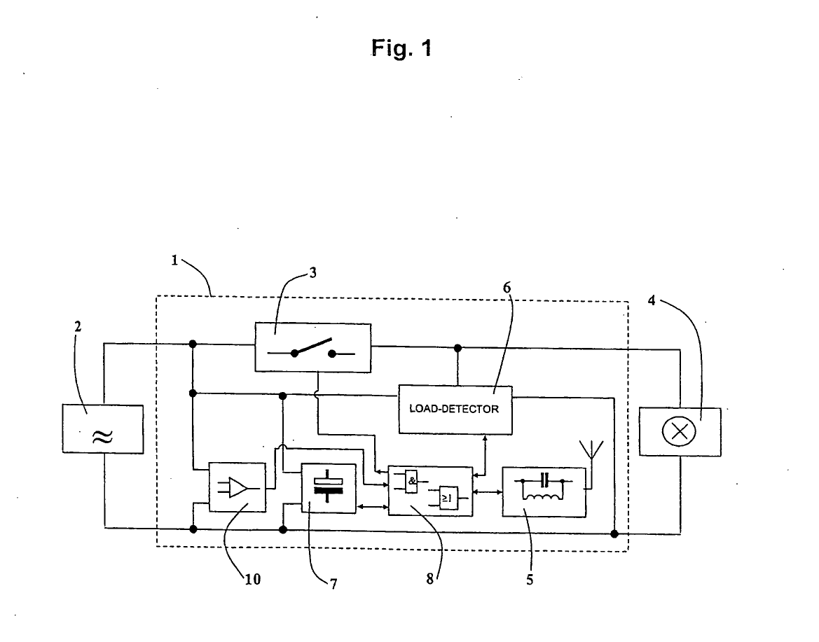

FIG. 1 shows a block diagram of a control apparatus in accordance with the invention,

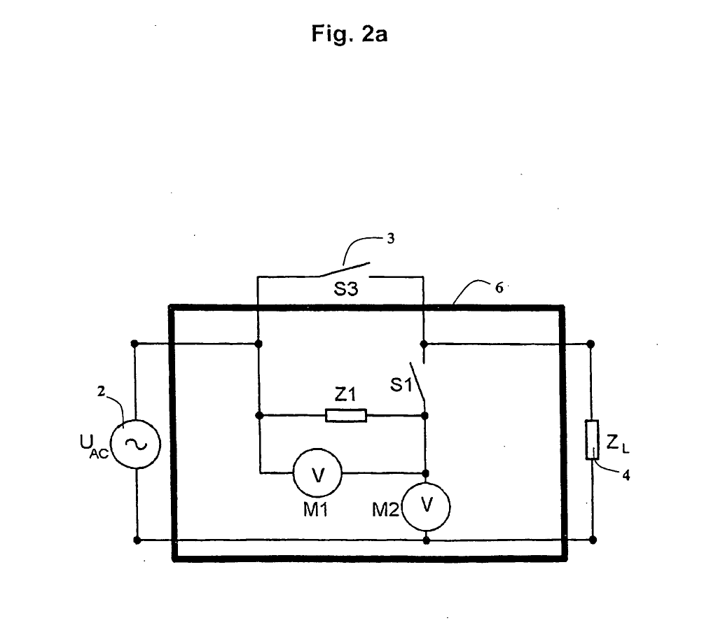

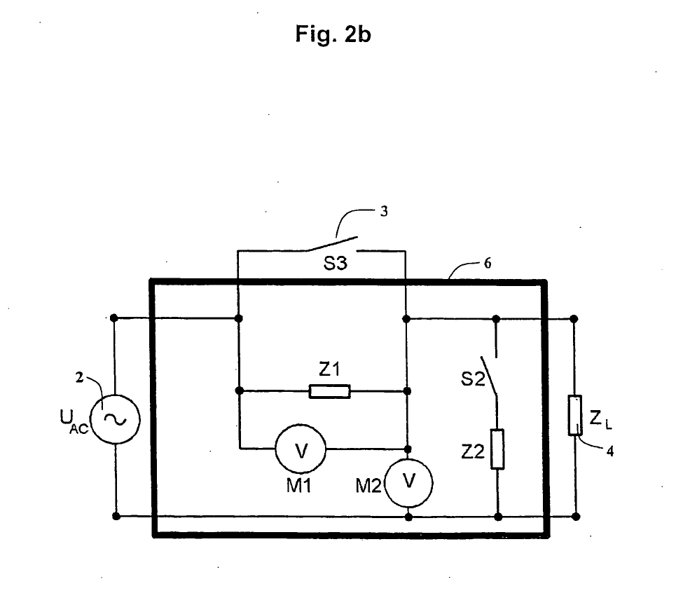

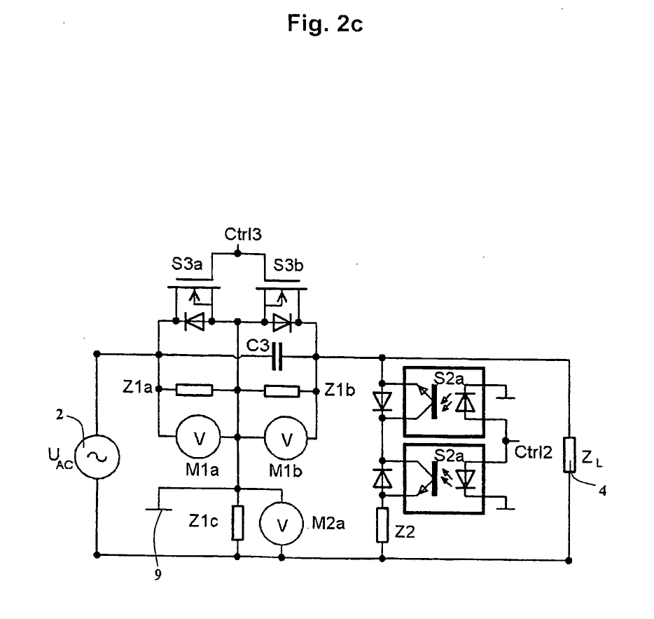

FIG. 2 shows circuit diagrams of various practical examples of the invention,

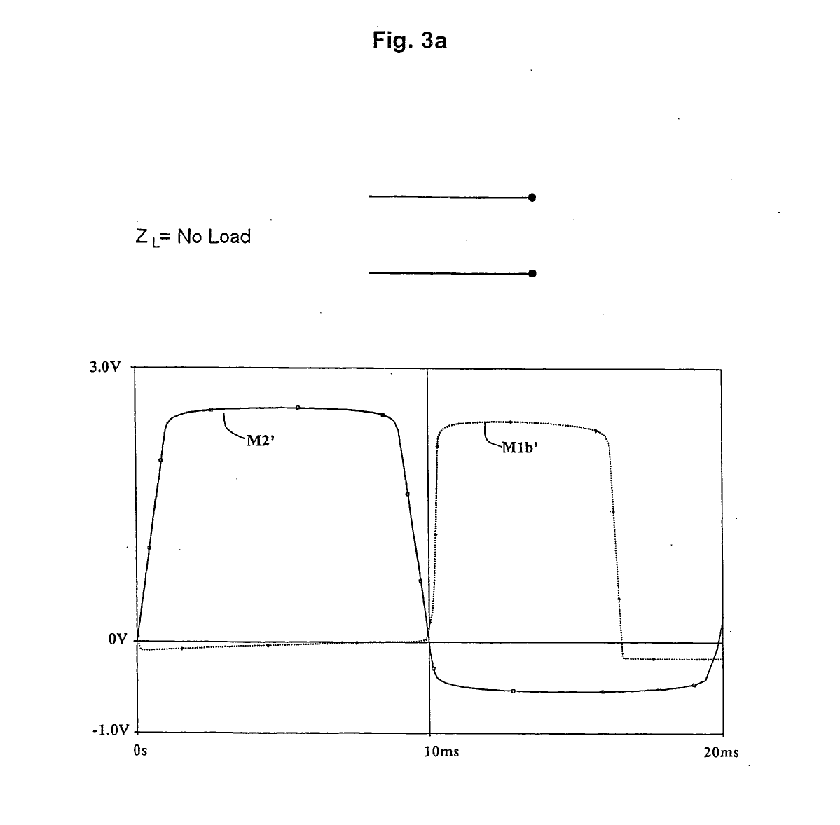

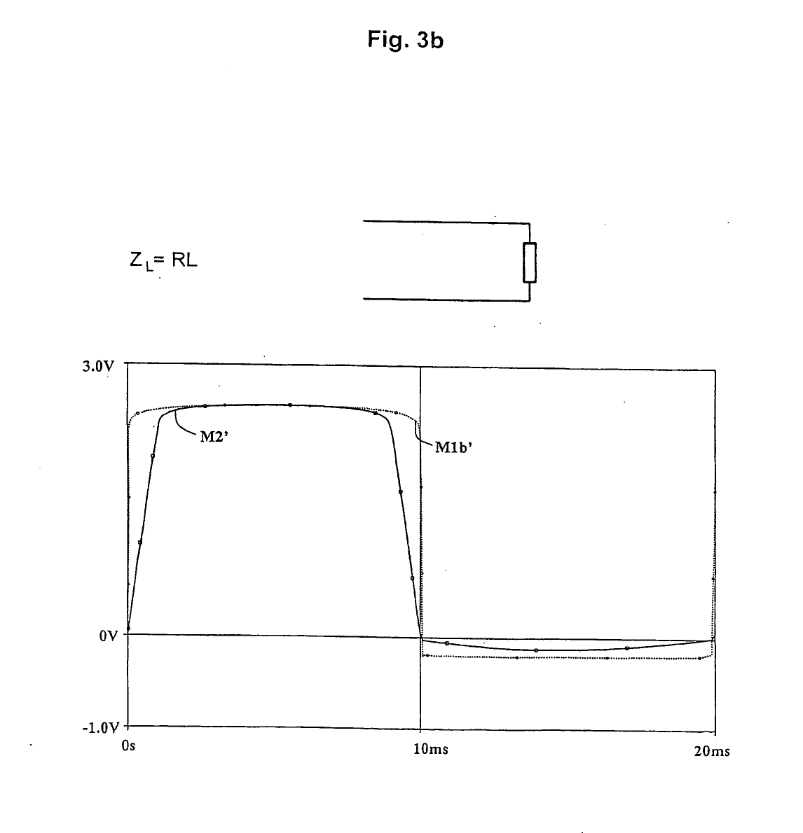

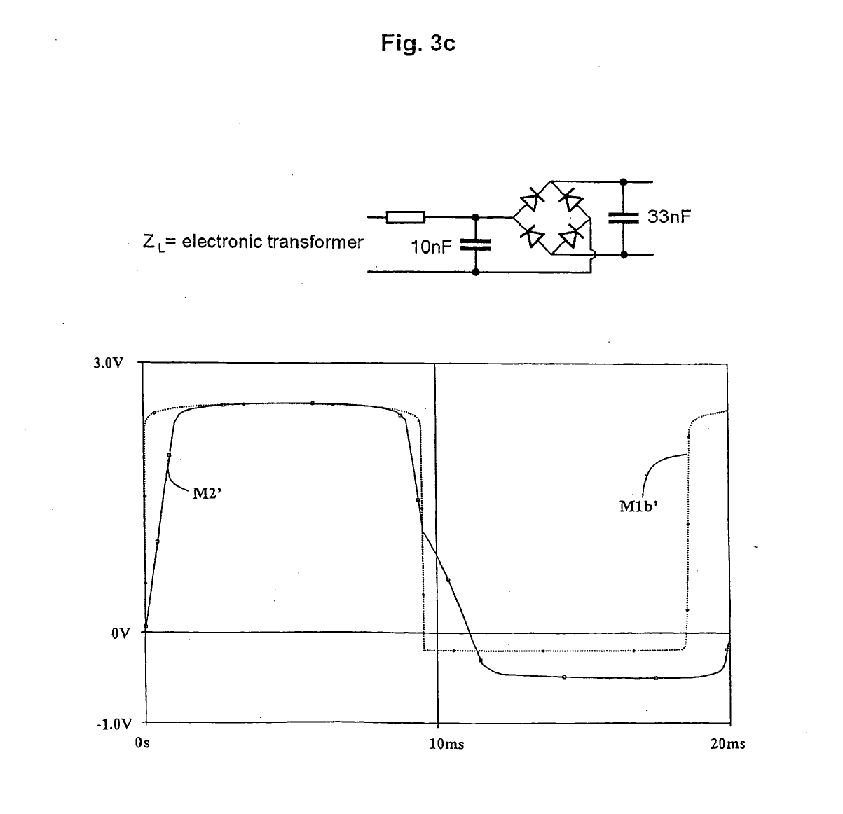

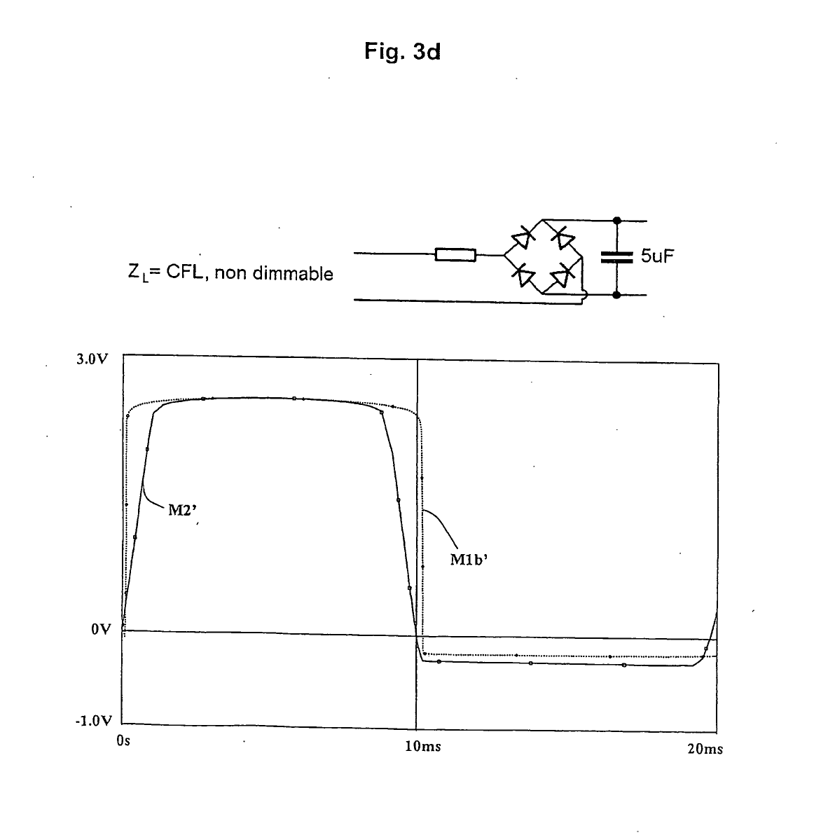

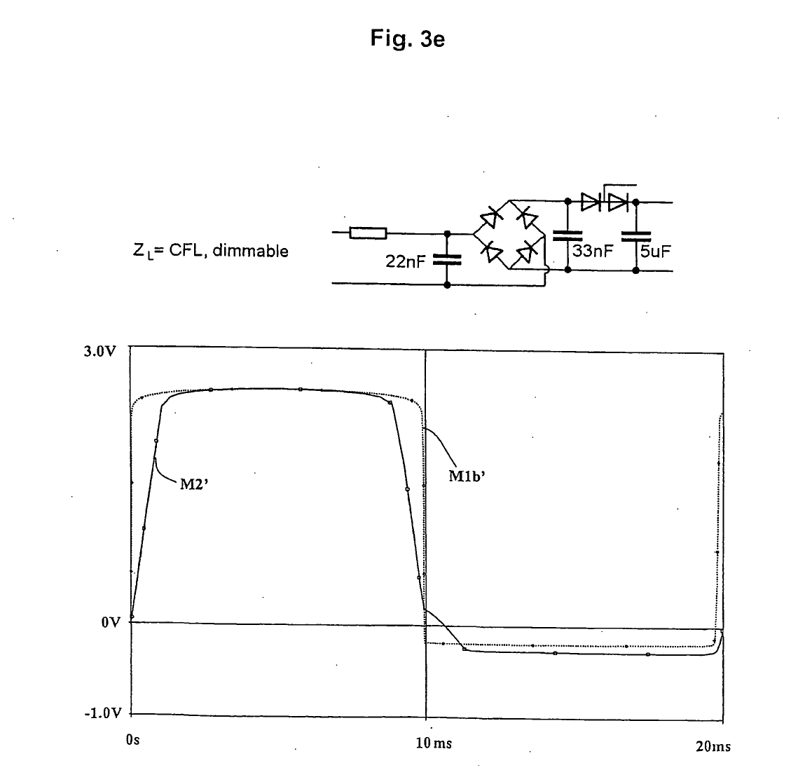

FIG. 3 shows the input circuit of exemplary load types as well as different measuring signal waveforms,

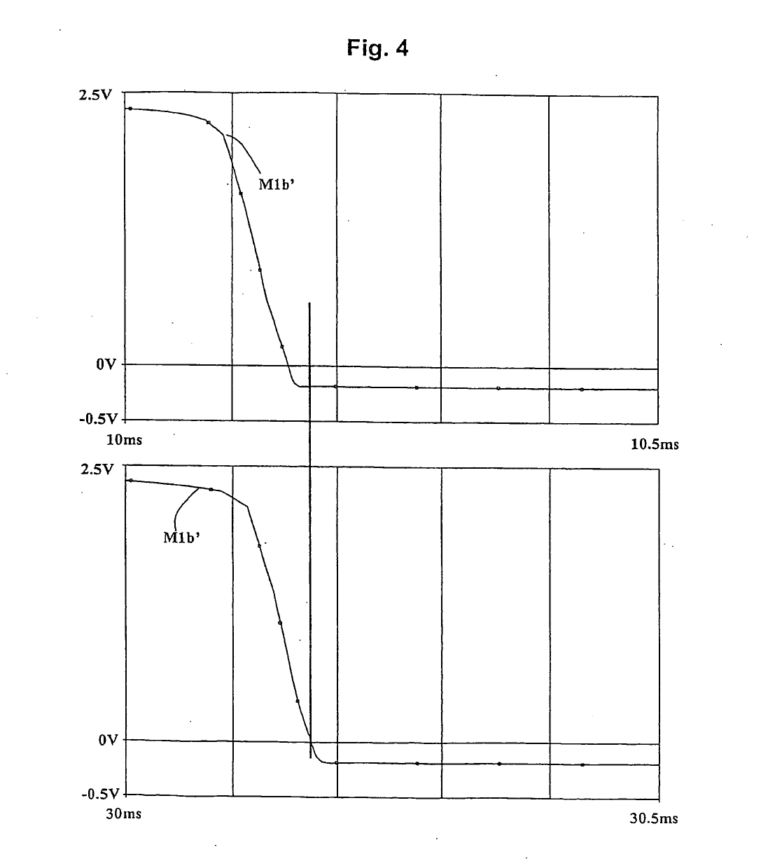

FIG. 4 shows an exemplary measuring signal waveform,

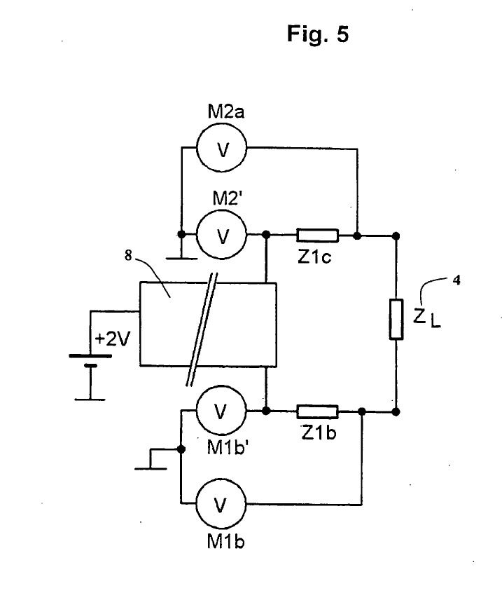

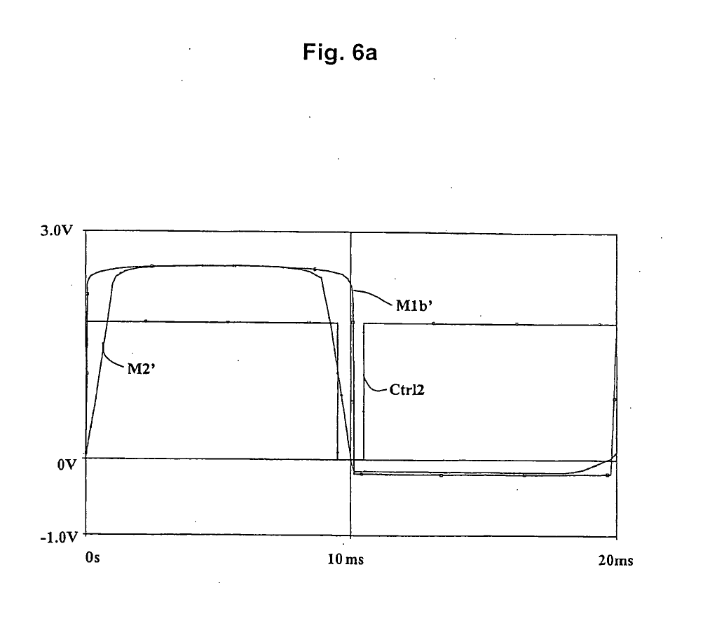

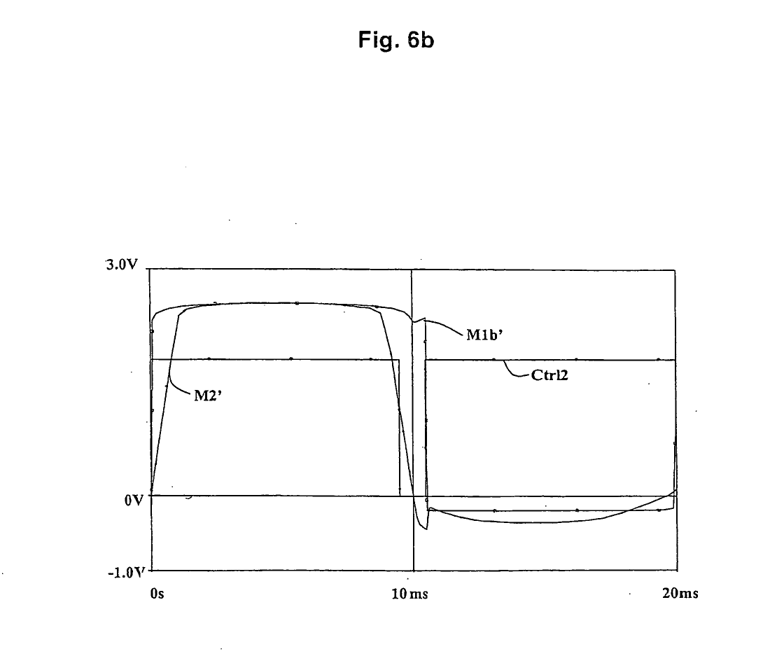

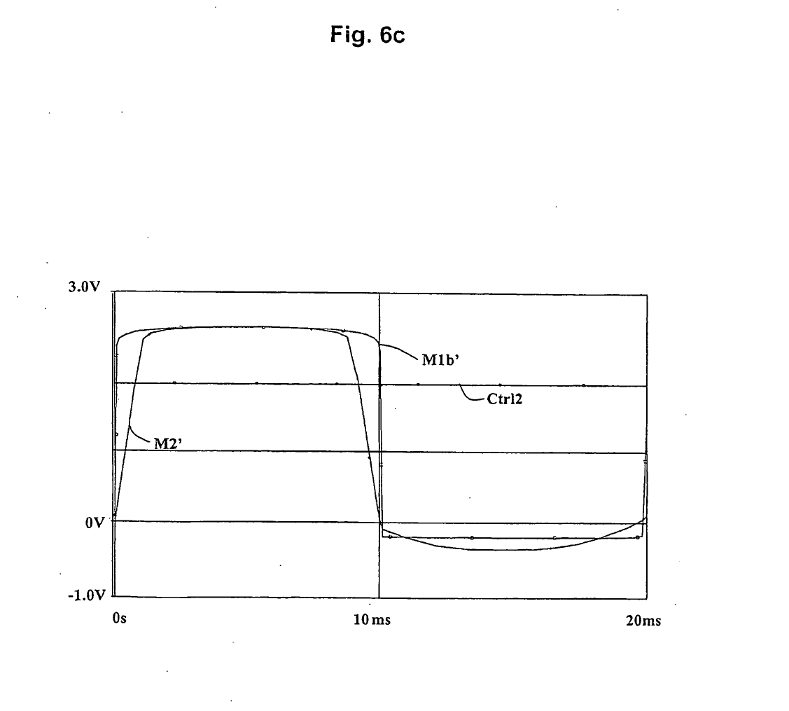

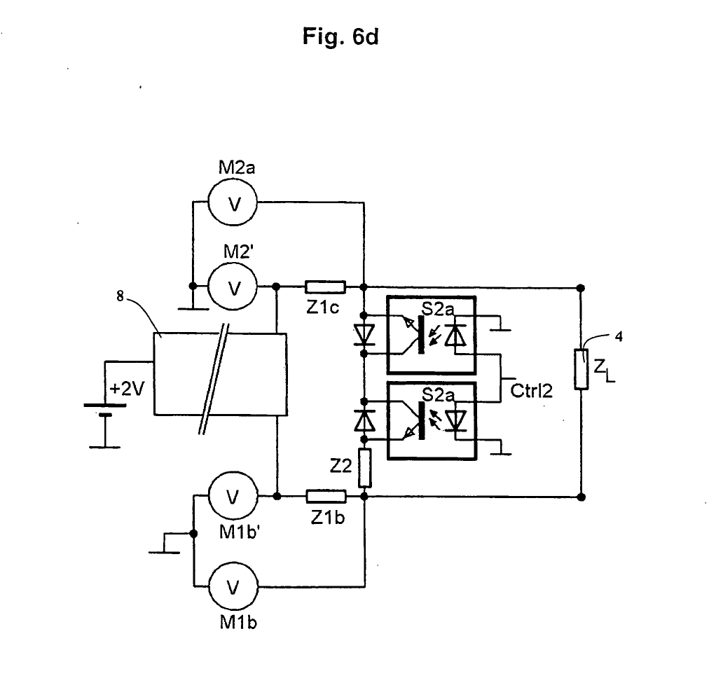

FIG. 5 shows a circuit diagram of another practical example of the invention, to FIG. 6 shows further exemplary measuring signal waveforms as well as a circuit diagram of another practical example,

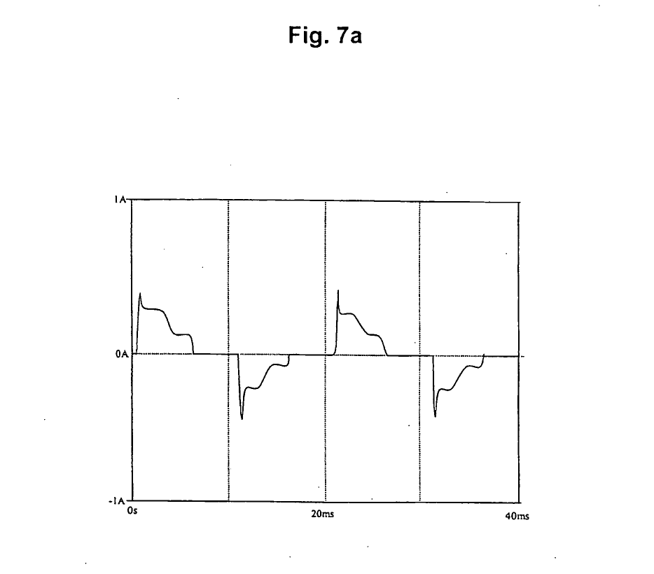

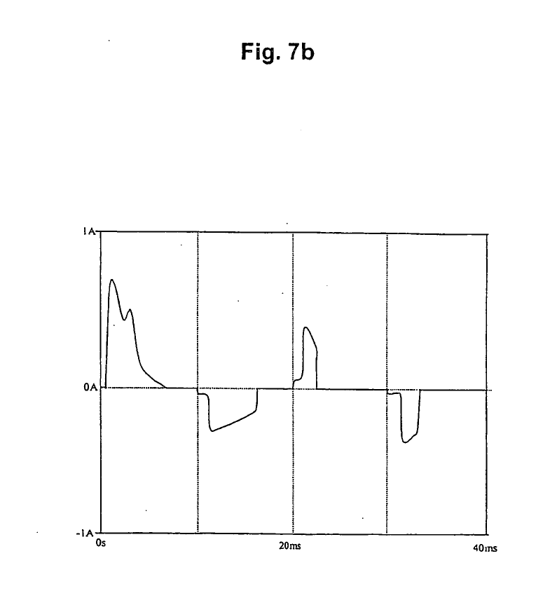

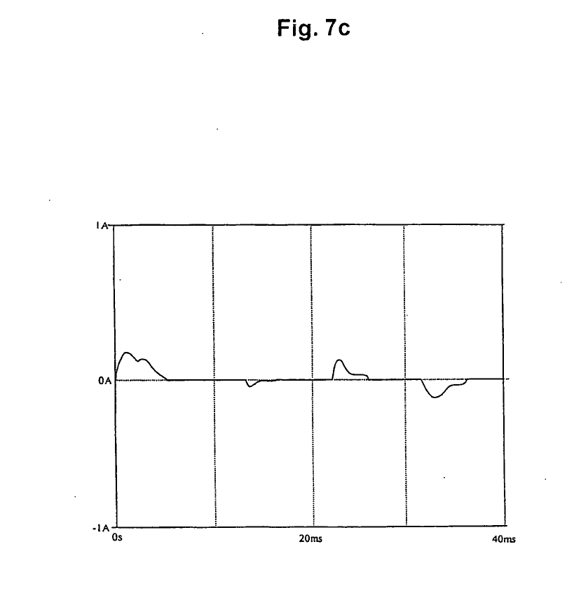

FIG. 7 shows exemplary test current waveforms.

The inventive control apparatus 1, as depicted in FIG. 1, is comprised of the functional units of a first switch 3, power supply 7, control circuit 8, and load type detector 6.

For controlling an a.c. load 4, an arrangement comprised of one or several separable semiconductor switches driven by a control circuit 8 according to a certain control method is utilized as first switch 3, e.g. in the sense of a reverse phase control or forward phase control or in accordance with another method in which the semiconductor switch 3 is switched on at a later moment during the period of mains current and switched off again at another moment during this period, e.g. in accordance with the method proposed in DE 37 27 058 A1.

Likewise, the control apparatus 1 may comprise a communication unit for exchange of remote control and status information with other devices or for integration into a wireless network like those available on the market, e.g. under the name ENOCEAN or Z-WAVE, or for integration into a wire-based network like KNX or LON, for example.

In addition, the control circuit 8, which will frequently be comprised of a microcontroller, will control all functional units of the control apparatus 1. It is also possible that the communication unit 5 contains a separate microcontroller to handle the communication protocol.

Furthermore, the depicted control apparatus 1 is comprised of a zero voltage detector 10 for recognizing the zero voltage crossing of the (alternating) voltage source 2 and a device for switching-off the first switch 3 in the zero crossing of the current flowing through the switch 3.

As shown in FIG. 2, the control apparatus 1 is equipped with a load type detector 6. FIG. 2a shows a first viable embodiment of the load type detector 6. Here, a series circuit comprised of the impedance Z1 and a second switch S1 is arranged in parallel to switch S3 which corresponds to the first switch 3 as per FIG. 1. In a first step of the inventive method, the second switch S1 is closed with switch S3 being open, i.e. with disconnected load 4, so that a test current flows through the load 4. By way of a smart dimensioning of the impedance Z1, e.g. 500 kOhm, this test current is limited to a value, preferably to <1 mA, which is insufficient for the operation of load 4 as intended. The test current should not lead to abnormal or externally perceivable operating statuses of the connected load 4, e.g. like visible light appearance in a luminaire connected as load 4.

In accordance with one embodiment of the invention, any arbitrary device instead of the impedance Z1 can be used which is capable of limiting the current to the desired test current (e.g. active transformers, passive construction elements). Here it is also possible that the test current is set dynamically, i.e. measurements taken with different test currents may enter into the detection of the type of load 4. Besides, the impedances for forming and limiting the test current cannot only be incorporated into the inventive device specifically for this purpose, but even those impedances that are in any way existing as a component of other hardware modules such as e.g. of the zero voltage detector 10 can also be utilized as impedances for this purpose.

It should be noted that the two switches S1 and S3 for controlling the test current flowing from the voltage source to the load circuit, i.e. to turn it on and off, are depicted here merely as examples. A switch in the sense of the invention, however, is any kind of a control or regulation device by means of which the flow of the test current and, if required, of the operating current, too, can be controlled.

In a second step of the inventive method, a first variable derived from the test current is measured by the aid of a voltage measuring device M1 and in parallel a second variable derived from the voltage at the load is determined by the aid of a voltage measuring device M2, executing a measuring series comprised of several measurements in the course of one or several periods of the mains to voltage with each voltage measuring device M1, M2 to represent the course of the test current and test voltage.

In a third step of the method, the control circuit 8 analyses the measuring results from the second step of the method for certain characteristic features relative to the signal waveform. In an exemplary configuration of the inventive method, the control circuit 8 determines for a predefined period relative to the zero crossing of the mains voltage whether e.g. predefined threshold values have been fallen short of or exceeded, or whether the value has changed relative to the value of the same period in the last period or whether the speed of change has fallen short of or exceeded a predefined threshold value.

The sum of the features determined results in a combination of characteristic features which the control circuit 8 allocates to a type of load in a fourth step of the method. In an exemplary configuration of the inventive method, this allocation is executed by comparison with data sets of a data field stored in the control circuit 8. In an exemplary configuration of the inventive object, this data field contains data sets for at least the following types of load:
1. No load;
2. Ohmic or inductive load;
3. Electronic transformer for operating a low-voltage bulb;
4. Energy-saving lamp with electronic ballast, not dimmable;
5. Energy-saving lamp with electronic ballast, dimmable;
6. LED-illuminants, not dimmable;
7. LED-illuminants, dimmable.

With the inventive method, upon completion of all measurements, switch S1 is opened again and thus the test current through load 4 is turned off to prevent a build-up of a load in a possibly existing electronic operating device of load 4 which might result in abnormal operating statuses of load 4 such as light artifacts which for example shows the energy-saving lamp of the type GENIE 8W of the company PHILIPS.

In summary, the inventive method for feeding current to load 4 is set up as follows: initially switch S3 is opened in the initial status. By closing switch S1, a to small test current is conducted as a test signal from the voltage source 2 to the load 4 by the control apparatus 1, with the test current being so limited that an operation of load 4 as intended is avoided, wherein the application of the test current results in a test voltage at the load 4. Thereupon, by means of measuring devices M1 and M2, a first variable derived from the test current and a second variable derived from the test voltage are determined throughout a predefined period of time, analyzing these two variables subsequently. From the chronology of the two variables throughout the predefined period of time, the type of load 4 can be determined now

It is also possible to determine the energy consumption, with it being possible to consider previous knowledge about certain properties of the load 4, e.g. nominal power absorbed, in the determination of the energy consumption. The individual process steps can be executed several times to determine a mean value of the load connected for measuring the energy consumption.

Finally, switch S3 is closed whereupon the operating current can flow to load 4 in a manner controlled by control apparatus 1.

FIG. 2b shows a second possible embodiment. Here, instead of the switch S1 shown in FIG. 2a, there is a series circuit comprised of switch S2 and impedance Z2 which here, too, serves for prevention of abnormal operating statuses conditioned by the test current at the actually switched-off load 4 in a way that switch S2 is closed and thus part of the test current flows through impedance Z2, e.g. 20 kOhm whereby the voltage evoked by the test current at the load 4 remains limited to a value under the starting voltage of the electronic operating device in load 4.

FIG. 2c shows a third exemplary embodiment which functionally corresponds to the variant shown in FIG. 2b and in which the switch S3 shown in FIG. 2b is realized by two MOSFETs S3a and S3b, switch S2 is executed in form of a series circuit comprised of two optocouplers S2a and S2b, and impedance Z1 is realized by means of impedances Z1a, Z1b, Z1c and C3, and wherein the voltage measuring device M1 is composed of the two measuring devices M1a and M1b, and wherein the voltage measuring device M2 corresponds to the sum of the measuring devices M2a and M1b. The special advantage of the embodiment shown in FIG. 2c as compared with the embodiment shown in FIG. 2b is the common signal ground 9 both of the voltage measuring devices M1a, M1b and M2a and of the two control signals Ctrl2 and Ctrl3, whereby these is signals can be connected without any major expenditure with the control circuit 8, in particular with the microcontroller contained therein, and whereby the voltage measuring devices M1a, M1b and M2a can be realized in form of a single voltage measuring device with an upstream located signal multiplexer.

In the exemplary configuration of the inventive device according to FIG. 2c, the impedances Z1a, Z1b, Z1c and C3 are not necessarily specifically incorporated into the inventive device, but are already a component of other construction modules there. For example, the impedances Z1a and Z1c may be a component part of the zero voltage detector 10 and limit the input current of the comparator there. In a special exemplary configuration, the impedances are realized by resistances which limit the input currents of the control circuit 8 and the zero voltage detector 10. Likewise, the capacitor C3 shown in FIG. 2c influences the test current. The values of the components, for example, amount to Z1a=400 kOhm, Z1b=1000 kOhm, Z1c=700 kOhm and C3=1 nF.

FIG. 3a to FIG. 3e show the input circuit of exemplary load types which are differentiated by the inventive device and the method, because each type of load has a characteristic input circuit which influences the test current in a different manner and thus also evokes different signal waveforms at the voltage measuring devices M1a, M1b and M2. In FIGS. 3a to 3e, exemplary signal waveforms M1b′ and M2′, allocated to the relevant input circuit of load 4, each for one period of the mains alternating voltage of 50 Hz as they are measured by means of the control circuit 8 according to FIG. 5. FIG. 4 shows that features in the signal waveform may vary throughout several periods of the alternating voltage. In the example shown here, the signal M1b′ recorded by the voltage measuring device alternates the polarity with a rising distance in time from the moment of the zero crossing of the 50 Hz alternating voltage. In the upper and/or lower clip of FIG. 4, the zero crossing occurs at 10 ms and/or 30 ms, and the polarity change occurs approx. 150 us and/or 170 us later, i.e. the temporal distance between zero crossing and polarity change of M1b′ increases by approx. 20 us per period.

Latest upon completion of the measurements, the control circuit 8 analyses the measured signal waveforms for features which are advantageously so chosen that their computation requires only a few milliseconds of computing time on a commercial-type 8-bit microcontroller. For the signal waveforms shown in FIGS. 3a to 3e, for example, the following features MM1 to MM5 can be chosen for detection of the type of load:
Feature MM1: M1b′ at the moment T=15 ms>1V
Feature MM2: M1b′ at the moment T=10 ms>1V
Feature MM3: M2′ at the moment T=10 ms>0.5V
Feature MM4: M1b′ at the moment T=19.9 ms>1V
Feature MM5: M2′ at the moment T=10 ms>1V

The features are so chosen that each type of load evidences one or more unambiguous feature combinations. In control circuit 8, the allocation between feature combination and type of load is stored in form of a data field so that it is accordingly easily possible to determine the type of load.

The following table shows an exemplary data field for allocation of a feature combination to a type of load:

| | Load Type | | | | |
|---|---|---|---|---|---|
| Feature | MM1 | MM2 | MM3 | MM4 | MM5 |
| FIG. 3a | 1 | 0 | 0 | 0 | 0 |
| FIG. 3b | 0 | 1 | 0 | 1 | 0 |
| FIG. 3c | 0 | 0 | 1 | 1 | 1 |
| FIG. 3d | 0 | 1 | 0 | 0 | 0 |
| FIG. 3e | 0 | 0 | 1 | 1 | 0 |

Legend:
0 = Feature exists/1 = Feature does not exist

It is possible to complement the list of detectible loads by further types of load by taking the relevant measurements for each further type of load and, for example by way of a visual comparison of the measuring curves, executing a feature extraction and then adapting or expanding the data field in the software of the control circuit 8 accordingly. It is also possible to implement a self-learning function for new loads, possibly upon a more precise specification by the user.

In the sense of the least possible data volume from the measurement and to the benefit of a simple and quick processing of the measuring values in the control circuit 8, it is advantageous to take measurements only during those periods of time within a period during which the crucial signal waveforms occur that are is relevant for taking a decision, e.g. near the zero crossings and in the middle of the half-wave of the alternating voltage rather than taking measurements spread equidistantly throughout the entire measuring period.

In terms of the least possible production cost of the inventive control apparatus, it is just as advantageous to pose only low requirements to absolute accuracy, linearity or resolution of the voltage measuring devices so that voltage measuring devices merely have at least such a recurring accuracy that the features derived from the signal waveforms do not vary crucially due to the recurring accuracy.

After the control circuit 8 has been able to allocate the determined feature combination to a data set and thus to determine the type of load, it will at first verify whether the determined type of load corresponds to the type shown in FIG. 3a, i.e. that no load is connected to the control apparatus 1, and in this case it will leave the test current activated and execute the inventive method again, commencing with the second step. The type of load “no load” illustrated in FIG. 2a may also correspond to a load which is not provided for connection to the control apparatus 1, e.g. a high-ohmic resistance of one megohm, for example.

Otherwise, if the determined type of load does not correspond to the variant illustrated in FIG. 3a, but the type of load is a variant which due to the test current demonstrates undesired reactions, like for example the type of load shown in FIG. 3d, the control circuit 8 will interrupt or reduce the test current through the load, for example in case of the variant according to FIG. 2c by activating the optocoupler shown there by a positive control current at the connection Ctrl2 and thus limiting the voltage evoked by the test current at the load to a value of e.g. 20 V. To ensure that the control circuit 8 recognizes the separation of the connection between load 4 and control apparatus 1 despite a disconnected or reduced test current, the control circuit 8 with particular advantage may again abolish for a short period of time this interruption or reduction of the test current within a period of time during which its momentary value is especially low, for example near the zero voltage crossing of voltage source 2. In this regard, FIGS. 6a to FIG. 6c show exemplary signal waveforms M1b′, M2′ and Ctrl2 for one type of load according to FIG. 3d for one period each of the alternating voltage of 50 Hz in the way as they occur at the control circuit 8 according to FIG. 6d with switch 3 being open, wherein FIG. 6a illustrates the signal waveforms for the case that the load 4 is connected with the control apparatus 1, and wherein FIG. 6b depicts the signal waveforms for the case that the same load 4 has been removed, and wherein in FIG. 6c in difference to FIG. 6b the test current has not been lowered. The comparison of FIG. 3d with FIG. 6a and of FIG. 6b with FIG. 6c shows that the removal of load 4 can be recognized based on signal M1b′.

It is also advantageous in terms of the invention, if specific control parameters can be allocated to each type of load, such as for example:
Control method, e.g. like reverse phase control, forward phase control, only ON/OFF, etc.;
Minimal value and maximal value, e.g. for output or phase angle;
Control curve, e.g. to offset a non-linear correlation between phase angle and brightness with illuminants;
Time-dependent limit values, e.g. minimal initial brightness with discharge lamps;
Information on whether a reduction of the test current is required after recognition of the load.

These control parameters can be stored in the table in the same data set which also contains the feature combination for recognition of the load.

Furthermore advantageously in terms of the invention, on recognition of an event that an electrical connection to load 4 has been established, the control circuit 8 performs an action, e.g. switching-on of load 4, or it transmits this information via the communication unit 5 to other devices which thereupon can perform an action. In case that load 4 is a lamp, it may be desired to switch it on automatically as soon as an electrical connection is established between the lamp and the control apparatus 1 in order to keep a possibly existing operating switch in the lamp functional from a user's point of view. It is practical to perform the verification of the electrical connection between control apparatus 1 and load 4 repeatedly within short time intervals, e.g. every 100 ms, so that from a user's point of view the reaction to the control event allocated to the establishment of the connection proceeds without any time lag.

In a very particularly advantageous configuration of the inventive control apparatus 1, it is so constructed that the time duration from establishing an electrical connection between voltage source 2 and control apparatus 1 through the determination of the type of load of a load 4 connected with the control apparatus until the possible switching-on of this load is not perceived by the user as an interfering delay (e.g. time duration <200 ms). This is achieved, for example, by constructing the power supply 7 in such a manner that the control apparatus 1 is ready to operate latest 100 ms after it has been connected with the voltage source 2 and that the control circuit 8 can then directly begin executing the inventive method. Thereby it is possible that an installation switch which is electrically located in series to control apparatus 1 remains functional from a user's point of view and that the control apparatus 1 can transmit the actuation of the installation switch via the communication unit 5 to other devices which can thereupon perform an action. For example, by actuating the to installation switch it is thus possible to switch-on another lamp that is connected to another control apparatus 1.

Upon recognition of the load 4 and of the pertinent type of load, the control apparatus 1 can switch on the load 4 on demand. This requisition can be triggered, for example, by a data package that is received from communication unit 5.

In an especially advantageous configuration of the invention, the control circuit 8 in a further step of the inventive method determines additional information on the load 4 by measuring and evaluating the operating current during switching-on and during the time after switching-on of the load. This additional information is particularly helpful in case that load 4 is an electronic operating device, for example in case of an energy-saving lamp or an LED illuminant, because with this type of load the necessary parameters for proper control of load 4 mainly result from the design and construction of the electronic operating device and for example because energy-saving lamps have differently designed and constructed operating devices, depending on type and manufacturer.

To execute this additional step for detection of the type of load in terms of the invention, the control circuit 8 will switch on the load 4 at a defined point of time within the period of mains voltage, e.g. at the moment of zero crossing of the voltage, and from then on measure the course of the operating current throughout one or several periods of the mains voltage. In the exemplary configuration of the inventive control apparatus 1 according to FIG. 2c, the operating current is determined by the aid of measuring devices M1a and M1b, with the voltage drop at the bulk resistance of the MOSFETs S3a and S3b shown there depicting the course of the operating current. FIG. 7a to FIG. 7d exemplary show the course of the operating current, measured from the moment of switching-on in the zero crossing of the mains voltage for the following types of load:

FIG. 7a: Energy-saving lamp with electronic ballast, not dimmable, MEGAMAN GA607 or PHILIPS Genie;

FIG. 7b: Energy-saving lamp with electronic ballast, dimmable, OSRAM, DULUX EL DIMMABLE 20W;

FIG. 7c: LED illuminant, dimmable PHILIPS MASTER LED Spot MV 7W.

To differentiate the illuminants according to FIGS. 7a to 7c, the measured course is of operating current is analyzed for certain features. For example, the following features could be investigated which are determined for each half-wave of the mains voltage:
Feature MM6: time duration from the last zero crossing of the mains voltage until the beginning of the flow of current.
Feature MM7: time duration of the flow of current.

The results of the evaluation of these exemplary features for the courses of current according to FIGS. 7a to 7c are shown in the following table:

| | Type of load | | | | |
|---|---|---|---|---|---|
| | | MM6 | MM7 | MM6 | MM7 |
| Feature | | 1.HW | 1.HW | 2.HW | 2.HW |

| | | | | | | |
|---|---|---|---|---|---|---|
| FIG. 7a | 0.6 | ms | 5.8 | ms | 1 ms | 5 ms |
| FIG. 7b | 0.6 | ms | 5.8 | ms | 0 ms | 6 ms |
| FIG. 7c | 0 | ms | 5 | ms | | |

Legend:
HW = Half-wave, 1. HW = 0 s <= t < 10 ms

Based on those values in the table printed in bold fonts, the control circuit 8 can recognize the type of load 4 latest in the second half-wave of the mains voltage after switching on of load 4.

Further features which may be investigated for differentiating the courses of operating current with a major number of different types of load are:
number of maximums and minimums in the current curve;
change in the increment of the current curve falls short of or exceeds a limit value;
maximum of the current within a temporal window.

The number of various design principles for electronic operating devices of energy-saving lamps or LED illuminants is limited inasmuch as individual manufacturers apply only a few (e.g. three) different design principles within the scope of their entire product range, and hence the total number of differentiations within the scope of the fifth step of the inventive method is is manageable.

With additional particular advantage, the control circuit 8 executes the latter step of detecting the type of load only with certain types of load, e.g. with energy-saving lamps and LED illuminants. Thereby it is avoided that types of load which are unsuitable for this variant of the inventive method, e.g. bulbs, demonstrate any interfering behavior on switching-on the load 4, such as for example a brief flashing-up.

Furthermore the configuration of the invention is of special advantage in that the measuring devices provided for executing the inventive method are utilized for determination of the energy consumption of the load, for example in that the value of the voltage at load 4 needed for computing the energy consumption in case of the inventive configuration according to FIG. 2c with switch 3 being open is determined by combination of the displayed values of the measuring devices M1a and M2a and in that the operating current value needed for computing the energy consumption is determined by combination of the displayed values of measuring devices M1b and M2a.

### LIST OF REFERENCE SIGNS

(1) Control apparatus
(2) Voltage source
(3) First switch
(4) Load
(5) Communication unit
(6) Load type detector
(7) Power supply
(8) Control circuit
(9) Signal ground
(10) Zero voltage detector

1. Control apparatus (1) for controlling a load (4), wherein the control apparatus (1) can be connected between a voltage source (2) and the load (4), having a control circuit (8), a first switch (S3) which is driven by the control circuit (8) and controls a current flowing from the voltage source (2) to the load (4) in order to operate the load (4), and a load type detector (6), wherein the load type detector (6) comprises means (Z1, Z2, S1, S2) for applying a test signal to the load (4) and at least one measuring device (M1, M2), wherein, for the purpose of detecting the type of load (4), the control apparatus (1) is set up to carry out the following first detection steps:
driving of the means (Z1, Z2, S1, S2) for applying the test signal to the load (4) by means of the control circuit (8) with the first switch (S3) open, wherein the application of the test signal results in a test current flowing through the load (4) and in a test voltage being dropped across the load (4),
recording of at least one variable derived from the test current and/or the test voltage by means of the measuring device (M1, M2),
and detection of the type of load by analyzing the recorded variable.

2. Control apparatus according to claim 1, wherein the test current is interrupted or reduced subsequent to executing the first detection steps.

3. Control apparatus according to claim 2, wherein the control apparatus is set up to carry out the following second detection steps subsequent to the first detection steps:
abolition of the interruption and/or of the reduction of the test current during a defined time interval, with the first switch (S3) being continually open,
detection of the at least one variable derived from the test current and/or test voltage by means of the measuring device (M1, M2) during the abolition of the interruption and/or reduction of the test current,
detection of a separation and/or restoration of the connection between the control apparatus (1) and the load (4) by analyzing the recorded variable.

4. Control apparatus according to claim 1, wherein the control apparatus is set up to carry out the following second detection steps:
driving of the means (Z1, Z2, S1, S2) for applying the test signal to the load (4) by means of the control circuit (8) with the first switch (S3) open,
recording of the at least one variable derived from the test current and/or test voltage by means of the measuring device (M1, M2),
detection of a separation and/or of a restoration of the connection between the control apparatus (1) and the load (4) by analyzing the recorded variable.

5. Control apparatus according to claim 1, wherein the test current is restricted during the first and/or second detection steps in such a manner that an operation of the load (4) as intended remains undone.

6. Control apparatus according to claim 1, wherein the control apparatus (1) is set up to repeatedly carry out the first and/or second detection steps.

7. Control apparatus according to claim 1, wherein the control apparatus (1) is set up to record a first variable derived from the test current and a second variable derived from the test voltage by means of the measuring device (M1, M2).

8. Control apparatus according to claim 1, wherein the detection of the load type is accomplished by analyzing the chronology of the at least one variable recorded.

9. Control apparatus according to claim 1, wherein the time for carrying out the first detection steps in total amounts to maximally 200 ms, preferably to maximally 100 ms.

10. Control apparatus (1) according to claim 1, wherein the control apparatus (1) is furthermore set up for controlling a current flowing from the voltage source (2) to the load (4) by means of the control circuit (8) after detection of the load type for operating the load by driving the first switch (S3) in accordance with a control method allocated to the load type.

11. Control apparatus (1) according to claim 1, furthermore comprising a communication unit (5) connected with the control circuit (8), wherein the communication unit (5) is configured to receive remote control data for remote control of the control apparatus (1) and/or to send status and/or diagnostic data of the control apparatus (1).

12. Control apparatus (1) according to claim 1, furthermore comprising a zero voltage detector (10) for detection of zero voltage crossings of the voltage source (2) connected with the control apparatus (1), wherein the moment of the beginning of recording the at least one variable derived from the test current and/or test voltage by the measuring device (M1, M2) relatively to the moment of a detected zero voltage crossing is predetermined.

13. Control apparatus (1) according to claim 1, wherein the control apparatus (1), for the purpose of analyzing the chronology of the first and/or second variable, is set up to carry out several measurements of the first and/or second variable at different predefined moments.

14. Control apparatus (1) according to claim 13, wherein the control apparatus (1) is furthermore set up to detect the load type by comparing the measuring values obtained at different predefined moments with stored data characterizing the load type.

15. Control apparatus (1) according to claim 1, comprising a second switch (S1) driven by the control circuit (8), said switch separably connecting the load (4) via at least one impedance (Z1) with the voltage source (2) for applying a test signal to the load (4).

16. Control apparatus (1) according to claim 1, comprising an impedance (Z1) switched in parallel to the first switch (S3) and by a second switch (S2) driven by the control circuit (8) which separably switches another impedance (Z2) in parallel to the load (4) for limiting the test current flowing through the load (4).

17. Control apparatus (1) according to claim 15, wherein the first switch (S3) and the second switch (S1, S2) are alternately opened or closed.

18. Control apparatus (1) according to claim 1, wherein the at least one measuring device (M1, M2) and the control circuit (8) have a common signal ground.

19. Control apparatus (1) according to claim 1, wherein the measuring device (M1, M2) is a voltage measuring device.

20. Control apparatus (1) according to claim 1, wherein the control apparatus is set up to carry out the following third detection steps:
applying an operating current to the load (4) by closing the first switch (S3),
recording at least one variable derived from the operating current and/or the operating voltage dropped across the load by means of the at least one measuring device (M1, M2),
detection of the type of load by analyzing the variable recorded.

21. Control apparatus (1) according to claim 20, wherein the control apparatus (1) is furthermore set up to carry out the closing of the first switch (S3) within a preset distance of time from the moment of a detected zero voltage crossing.

22. Method for detection of a type of load (4), more particularly by using a control apparatus according to claim 1, wherein the load (4) can be connected with a voltage source (2) via a first switch (S3) which controls a current flowing to the load (4) to operate the load (4), comprising the following first detection steps:
applying a test signal to the load (4) with the first switch (S3) open, wherein applying the test signal results in a test current flowing through the load (4) and in a test voltage dropped across the load (4),
recording at least one variable derived from the test current and/or test voltage,
detection of the load type by analyzing the chronology of the at least one variable recorded.

23. Method according to claim 22, comprising the following second detection step:
interrupting or reducing the test current after detection of the type of load.

24. Method according to claim 22, comprising the following second detection steps:
applying the test signal to the load (4) with the first switch (S3) open,
recording the at least one variable derived from the test current and/or test voltage,
detection of a separation or of a restoration of a connection to the load (4) by analyzing the variable recorded.

25. Method according to claim 22, wherein the test current is limited during the first and/or second detection steps in such a manner that an operation of the load (4) as intended remains undone.

26. Method according to claim 22, comprising the following third detection steps:
applying an operating current to the load (4) by closing the first switch (S3),
recording at least one variable derived from the operating current and/or from an operating voltage dropped across the load (4),
detection of the load type by analyzing the variable recorded.

27. Computer program product with instructions executable by a processor to carry out the detection steps of the method according to claim 22.
